(19) United States
(12) Patent Application Publication
(10) Pub. No.: US 2009/0160462 A1
(43) Pub. Date: Jun. 25, 2009

(54) MICROELECTROMECHANICAL CAPACITOR BASED DEVICE

(76) Inventor: DIVYASIMHA HARISH, Fremont, CA (US)

Correspondence Address: Intellevate, P.O. Box 52050, Minneapolis, MN, 55402, US

(21) Appl. No.: 12/342,853

(22) Filed: Dec. 23, 2008

Related U.S. Application Data
(60) Provisional application No. 61/016,464, filed on Dec. 23, 2007.

(51) Int. Cl. G01R 27/26; H01G 7/00

(52) U.S. Cl. 324/686; 29/25.41

(57) ABSTRACT

A system and methods of a microelectromechanical capacitor based device are disclosed. In one embodiment, a system of a microelectromechanical capacitive device includes a housing formed when a nonconductive material is deposited on a substrate, and a conductive plate mechanically coupled to the housing. The system further includes an additional housing coupled to the housing and an additional conductive plate that is substantially parallel to the conductive plate. The additional conductive plate is coupled to the additional conductive plate. The additional housing may be formed when an additional nonconductive material is deposited on an additional substrate. The substrate and the additional substrate may be dissolved using a chemical etching process when the housing and the additional housing are coupled.

### CLAIM OF PRIORITY

This application claims priority from U.S. Provisional Patent Application No. 61/016,464 filed on Dec. 23, 2007.

### FIELD OF TECHNOLOGY

This disclosure relates generally to the field of measuring devices and, in one example embodiment, to a system and methods of a microelectromechanical capacitor based device.

### BACKGROUND

Various devices (e.g., a medical device such as a catheter and/or an auto part such as a tire pressure sensor) may depend on sensor technology. Such a sensor may be a transducer which converts one type of energy (e.g., a pressure, force, etc.) to another type (e.g., an electrical signal). When a dependent device comes in small size, the sensor embedded in the dependent device has to be in microscopic scale.

However, in the case of the miniaturized sensor, it may be difficult to withstand the pressure, force, and/or other form of energy applied to the sensor (e.g., thus causing it to wear out prematurely). Furthermore, the dependent device may need to be interrupted (e.g., during its operation) and/or deconstructed to recharge or replace a power source of the sensor. This may be troublesome when the sensor is installed in the dependent device (e.g., the tire) such that the sensor is nearly impossible to access.

### SUMMARY

A system and methods of a microelectromechanical capacitor based device are disclosed. In one aspect, a system of a microelectromechanical capacitive device includes a housing formed when a nonconductive material is deposited on a substrate, and a conductive plate mechanically coupled to the housing. The system further includes an additional housing coupled to the housing and an additional conductive plate that is substantially parallel to the conductive plate. The additional conductive plate is coupled to the additional conductive plate.

The additional housing may be formed when an additional nonconductive material is deposited on an additional substrate. The substrate and the additional substrate may be dissolved using a chemical etching process when the housing and the additional housing are coupled. The microelectromechanical capacitive device may be used to detect a change in capacitance when a gap between the conductive plate and the additional conductive plate is changed. The microelectromechanical capacitive device may be used to detect a change in capacitance when an overlapping area of the conductive plate and of the additional conductive plate is changed.

The system may include a supplementary pair of conductive plates, and the microelectromechanical capacitive device may be used to detect a change in capacitance when an overlapping area of the supplementary pair of conductive plates is changed. The system may also include a reference sensor coupled to the housing to generate a capacitance based on an environmental factor and to compensate a measurement affected by the environmental factor.

The system may further include a plurality of capacitors in the housing, wherein a difference in capacitance between the plurality of capacitors is used to detect an uneven force when it is applied to the housing. The system may include a solid and/or a semisolid dielectric material located between the conductive plate and the additional conductive plate.

They system may also include a tip of a catheter that is mechanically coupled to the housing. The system may detect a force when it is applied to the tip of the catheter and it causes an additional force to act on the housing. The system may include a container coupled to the housing. The container may hold a medicine, and a weight of the medicine may be determined by a capacitance between the conductive plate and the additional conductive plate when a force is applied to the housing.

The system may include a tire physically coupled to the housing, and a measurement module to obtain a tire pressure measurement when a force is applied to the housing. The measurement module may be electrically coupled to the conductive plate and the additional conductive plate. The system may also include a communication module, which may be used to communicate the tire pressure measurement when a force is applied to the housing. The system may also include an energy harvesting module, wherein the energy harvesting module acquires a kinetic energy of the tire when the tire is moving, stores the kinetic energy, and powers the measurement module when it obtains the tire pressure measurement. The tire pressure measurement may be communicated using one or more of wireless universal serial bus, Wi-Fi, Bluetooth, and Zigbee.

In another aspect, the method of a microelectromechanical capacitive device includes depositing a nonconductive material on a substrate to form a housing, and depositing an additional nonconductive material on an additional substrate to form an additional housing. The method further includes mechanically coupling a conductive plate to the housing, and mechanically coupling an additional conductive plate to the additional housing. The method also includes forming the microelectromechanical device when the housing and the additional housing are mechanically coupled, such that the conductive plate and the additional conductive plate are substantially parallel.

The method may include dissolving the substrate and the additional substrate using a chemical etching process. The microelectromechanical capacitive device may be used to detect a change in capacitance when a gap between the conductive plate and the additional conductive plate is changed. The microelectromechanical capacitive device may be used to detect a change in capacitance when an overlapping area of the conductive plate and of the additional conductive plate is changed.

In yet another aspect, a method of a microelectromechanical capacitive device includes receiving an applied force with a housing formed when a nonconductive material is deposited on a substrate, and deflecting the housing in response to the applied force. The method further includes shifting the conductive plate coupled to the housing relative to an additional conductive plate using the deflection of the housing. The additional conductive plate is mechanically coupled to an additional housing. The method further includes detecting a change in capacitance using a change of at least one of a gap between the conductive plate and the additional conductive plate and an overlapping area of the conductive plate and the additional conductive plate. The method may include detecting a capacitance based on an environmental factor using a reference sensor in the housing, and compensating a measurement affected by the environmental factor.

Other features of the present embodiments will be apparent from the accompanying drawings and from the detailed description that follows.

### BRIEF DESCRIPTION OF THE DRAWINGS

Example embodiments are illustrated by way of example and not limitation in the figures of the accompanying drawings, in which like references indicate similar elements and in which:

FIGS. 1A and 1B are exemplary cross-sectional views of a gap changing microelectromechanical capacitive device, according to embodiments of the present invention.

FIG. 1C is an exemplary operational view of the gap changing microelectromechanical capacitive device of FIGS. 1A and 1B, according to embodiments of the present invention.

FIGS. 2A and 2B are exemplary cross-sectional views of an area changing microelectromechanical capacitive device, according to embodiments of the present invention.

FIG. 2C is an exemplary operational view of the area changing microelectromechanical capacitive device of FIGS. 2A and 2B, according to embodiments of the present invention.

FIGS. 3A and 3B are exemplary cross-sectional views of a microelectromechanical capacitive device based on changes in both the gap and overlap area of conductor plates of the microelectromechanical capacitive device, according to embodiments of the present invention.

FIG. 4A is an exemplary process for fabricating an upper part of the housing of the gap changing microelectromechanical capacitive device in FIGS. 1A, 1B, and 1C, according to embodiments of the present invention.

FIG. 4B is an exemplary process for fabricating a lower part of the housing of the gap changing microelectromechanical capacitive device in FIGS. 1A, 1B, and 1C, according to embodiments of the present invention.

FIG. 4C is an exemplary process for assembling the upper housing formed in FIG. 4A and the lower housing formed in FIG. 4B, according to embodiments of the present invention.

FIGS. 5A and 5B are exemplary cross sectional views of the gap changing microelectromechanical capacitive device of FIG. 1A with a solid dielectric material filling the inner cavity of the housing, according to embodiments of the present invention.

FIG. 6 is an exemplary block diagram of a microelectromechanical capacitive device, according to embodiments of the present invention.

FIG. 7 is an exemplary diagram of a catheter system based on one or more sensors, according to embodiments of the present invention.

FIG. 8 is an exemplary vertical cross sectional view of the tip end of the catheter of FIG. 7 equipped with a MEM capacitor device, according to embodiments of the present invention.

FIG. 9 is a horizontal cross sectional view of the tip end of the catheter of FIG. 7, according to embodiments of the present invention.

FIG. 10 is an exemplary diagram of an inhaler having a pressure sensor to weigh medicine remaining in a medicine canister of the inhaler, according to embodiments of the present invention.

FIG. 11 is an exemplary diagram of an inhaler kit with an inhaler and an inhaler stand equipped with a pressure sensor to weigh medicine remaining in a medicine canister of the inhaler, according to embodiments of the present invention.

FIG. 12 is an exemplary diagram of a control module of a tire interacting with an access module to check a tire pressure, according to embodiments of the present invention.

FIG. 13 is an exemplary block diagram of the control module of FIG. 12, according to embodiments of the present invention.

Other features of the present embodiments will be apparent from the accompanying drawings and from the detailed description that follows.

### DETAILED DESCRIPTION

Reference will now be made in detail to the preferred embodiments of the invention, examples of which are illustrated in the accompanying drawings. While the invention will be described in conjunction with the preferred embodiments, it will be understood that they are not intended to limit the invention to these embodiments. On the contrary, the invention is intended to cover alternatives, modifications and equivalents, which may be included within the spirit and scope of the invention as defined by the claims. Furthermore, in the detailed description of the present invention, numerous specific details are set forth in order to provide a thorough understanding of the present invention. However, it will be obvious to one of ordinary skill in the art that the present invention may be practiced without these specific details. In other instances, well known methods, procedures, components, and circuits have not been described in detail as not to unnecessarily obscure aspects of the present invention.

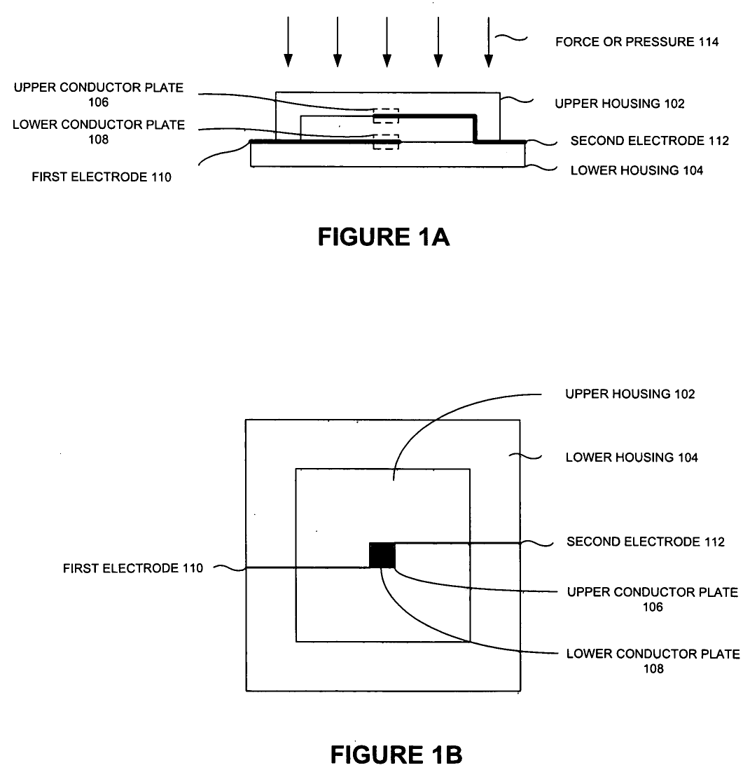

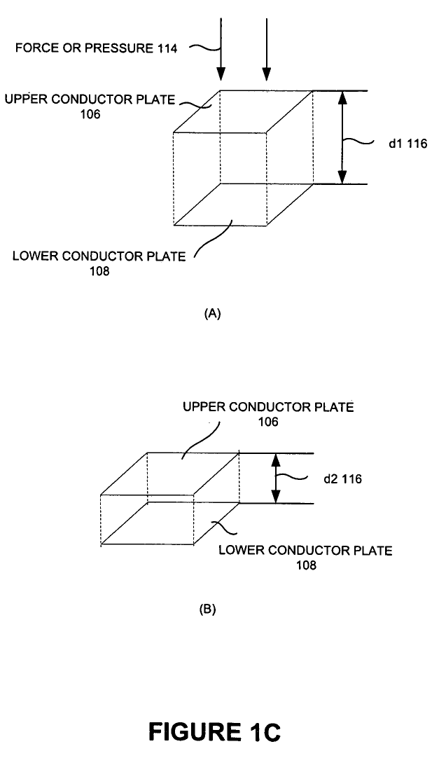

FIGS. 1A and 1B are exemplary cross-sectional views of a gap changing microelectromechanical capacitive device, according to embodiments of the present invention. As illustrated in FIGS. 1A and 1B, the gap changing microelectromechanical capacitive device (e.g., sensor) includes an upper housing 102, a lower housing 104, an upper conductor plate 106, a lower conductor plate 108, a first electrode 110, and a second electrode 112.

A capacitor is formed between the upper conductor plate 106 and the lower conductor plate 108 (e.g., substantially parallel to each other) when a uniform voltage is applied between the first electrode 110 (e.g., which connects to the lower conductor plate 108) and the second electrode 112 (e.g., which connects to the upper conductor plate 106). As will be illustrated in details in FIG. 1C, a force or pressure 114 applied on top of the upper housing 102 causes the upper housing 102 to deflect toward the lower housing 104, thus resulting in a change in capacitance.

The change in capacitance is fed to a circuit (e.g., a Wheatstone Bridge based on one or more of capacitors and/or resistors) which converts to its electrical value. The upper housing 102 and the lower housing 104 may be made of a non-conductive material. The upper conductor plate 106 and the lower conductor plate 108 may be made of a conductive material and/or a semiconductor material. The first electrode 110 and the second electrode 112 may be made of metal.

The shape of the upper housing 102 and the lower housing 104 may take the shape of a circle, a triangle, a square, a rectangular, a pentagon, a hexagon, an octagon, and so on. Likewise, the shape of the upper conductor plate 106 and the lower conductor plate 108 may take the shape of a circle, a triangle, a square, a rectangular, a pentagon, a hexagon, an octagon, and so on.

In one example embodiment, multiple sets of the upper conductor plate 106 and the lower conductor plate 108 (e.g., three) may be formed inside the housing to make the gap changing microelectromechanical capacitive device more sensitive to an applied force or pressure 114 applied. Accordingly, the installation of multiple sets of the conductor plates may make it easier to calibrate the gap changing microelectromechanical capacitive device.

FIG. 1C is an exemplary operational view of the gap changing microelectromechanical capacitive device of FIGS. 1A and 1B, according to embodiments of the present invention. In the initial state of the gap changing microelectromechanical capacitive device as illustrated in FIG. 1C (A), the distance between the upper conductor plate 106 and the lower conductor plate 108 is d1 116. When a force or pressure 114 is applied to the microelectromechanical capacitive device as illustrated in FIG. 1C (B), the distance between the upper conductor plate 106 and the lower conductor plate 108 is decreased to distance d2 116.

Because C=kA/D where C=capacitance, k=constant, A=area, and D=distance, the capacitance due to the force or pressure 114 increases as the distance between the two plates (e.g., the upper conductor plate 106 and the lower conductor plate 108) decreases. The change in capacitance is routed to a circuit which converts it to an electrical value (e.g., a voltage, a frequency, etc.).

In one example embodiment, the microelectromechanical capacitive device is a capacitor with a pair of conductor plates (e.g., parallel to each other) contained in a housing made of a non-conductive material. A circuit (e.g., internal or external to the microelectromechanical capacitive device) connects to electrodes of the microelectromechanical capacitive device to measure a capacitance change of the capacitor based on a deflection of the housing (e.g., thus decreasing the distance between the two conductor plates) due to a force or a pressure applied to the housing. The pair of conductor plates may be formed through applying a conductive material to one or more areas (e.g., the inner surface) of the housing.

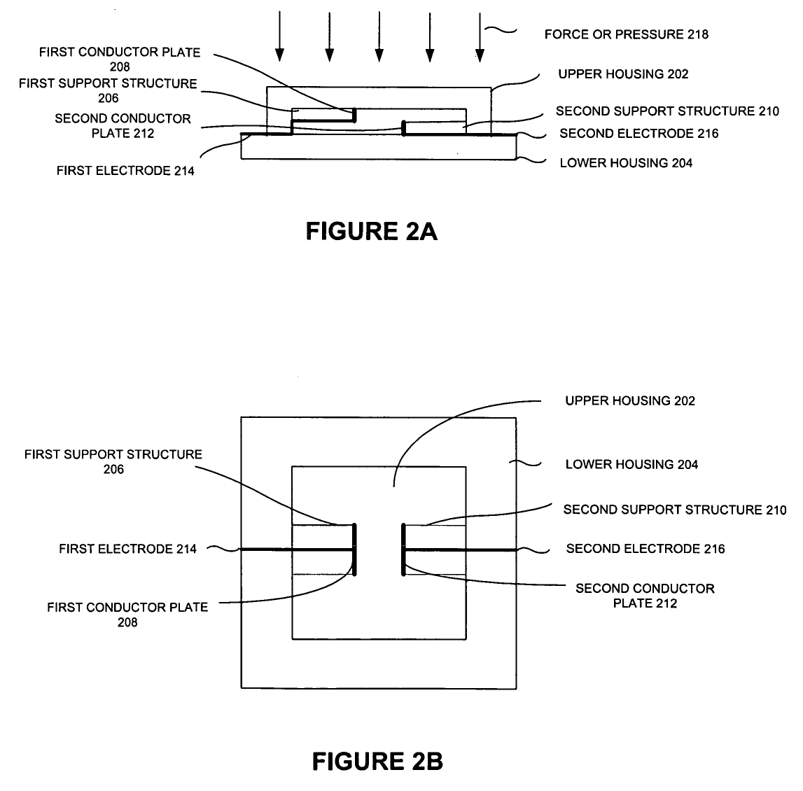

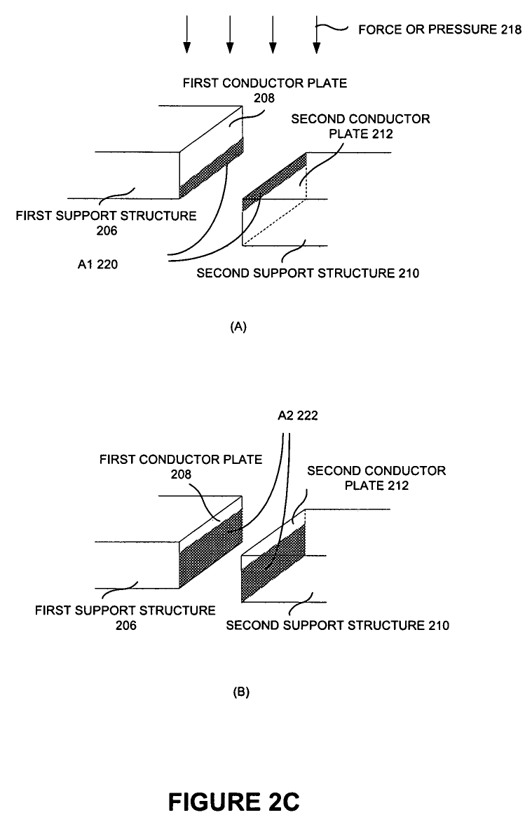

FIGS. 2A and 2B are exemplary cross-sectional views of an area changing microelectromechanical capacitive device, according to embodiments of the present invention. As illustrated in FIGS. 2A and 2B, the area changing microelectromechanical capacitive device (e.g., sensor) includes an upper housing 202, a lower housing 204, a first support structure 206, a first conductor plate 208, a second support structure 210, a second conductor plate 212, a first electrode 214, and a second electrode 216.

A capacitor is formed when there is an overlap between the first conductor plate 208 and the second conductor plate 212 (e.g., substantially parallel to each other) while a uniform voltage is applied between the first electrode 214 (e.g., which connects to the first conductor plate 208) and the second electrode 216 (e.g., which connects to the second conductor plate 212). As will be illustrated in details in FIG. 2C, a force or a pressure 218 applied on top of the upper housing 202 causes the first conductor plate 208 to move closer to the second conductor plate 212, thus resulting in a change in capacitance (e.g., due to a change in the area overlapping the first conductor plate 208 and the second conductor plate 212).

The change in capacitance is also fed to a circuit (e.g., a Wheatstone Bridge based on one or more of capacitors and/or resistors) which converts to its electrical value. The upper housing 202 and the lower housing 204 may be made of a non-conductive material. The first conductor plate 208 and the second conductor plate 212 may be made of a conductive material and/or a semiconductor material. The first electrode 214 and the second electrode 216 may be made of metal.

The shape of the upper housing 202 and the lower housing 204 may take the shape of any geometry, for instance, a circle, a triangle, a square, a rectangular, a pentagon, a hexagon, an octagon, and so on. Likewise, the shape of the first conductor plate 208 and the second conductor plate 212 may take the shape of any geometry, such as a circle, a triangle, a square, a rectangular, a pentagon, a hexagon, an octagon, and so on.

In one example embodiment, multiple sets of the first conductor plate 208 (e.g., with the first support structure 206) and the second conductor plate 212 (e.g., with the second support structure 210) may be formed inside the housing to make the area changing microelectromechanical capacitive device more sensitive to the force or pressure 218 applied. Accordingly, the installation of multiple sets of the conductor plates may make it easier to calibrate the area changing microelectromechanical capacitive device.

FIG. 2C is an exemplary operational view of the area changing microelectromechanical capacitive device of FIGS. 2A and 2B, according to embodiments of the present invention. In the initial state of the area changing microelectromechanical capacitive device as illustrated in FIG. 2C (A), the overlap area between the first conductor plate 208 (e.g., formed on the first support structure 206) and the second conductor plate 212 (e.g., formed on the second support structure 210) is shown as A1 220. When the force or pressure 218 is applied to the microelectromechanical capacitive device as illustrated in FIG. 2C (B), the overlap area between the first conductor plate 208 and the second conductor plate 212 is increased to A2 222.

Because C=kA/D where C=capacitance, k=constant, A=area, and D=distance, the capacitance due to the force or pressure 218 increases as the overlap area between the two plates (e.g., the first conductor plate 208 and the second conductor plate 212) increases. The change in capacitance is also routed to the circuit which converts it to an electrical value (e.g., a voltage, a frequency, etc.).

In one example embodiment, the microelectromechanical capacitive device is a capacitor with a pair of conductor plates (e.g., parallel to each other) contained in a housing made of a non-conductive material. A circuit (e.g., internal or external to the microelectromechanical capacitive device) connects to electrodes of the microelectromechanical capacitive device to measure a capacitance change of the capacitor based on a deflection of the housing (e.g., thus increasing the area overlapped by the two conductor plates) due to a force or a pressure applied to the housing. The pair of conductor plates may be formed through building one or more support structures extending from the housing and applying a conductive material to one or more areas of the support structures.

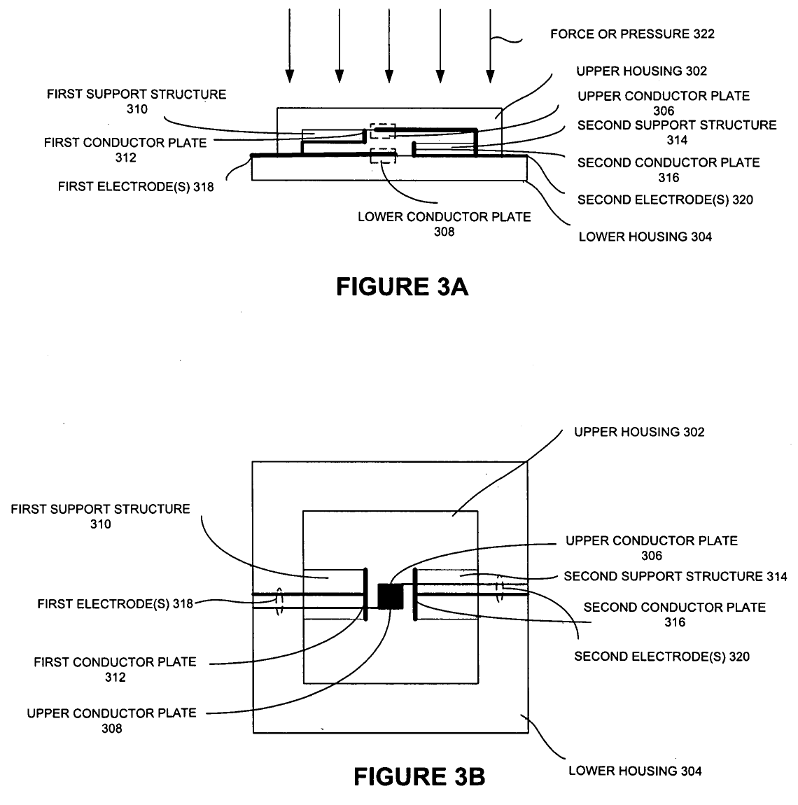

FIGS. 3A and 3B are exemplary cross-sectional views of a microelectromechanical capacitive device based on changes in both the gap and overlap area of conductor plates of the microelectromechanical capacitive device, according to embodiments of the present invention. As illustrated in FIGS. 3A and 3B, the microelectromechanical capacitive device (e.g., sensor) includes an upper housing 302, a lower housing 304, a upper conductor plate 306, a lower conductor plate 308, a first support structure 310, a first conductor plate 312, a second support structure 314, a second conductor plate 316, a first electrode 318, and a second electrode 320.

Two capacitors are formed based on a gap changing capacitor between the upper conductor plate 306 and the lower conductor plate 308 (e.g., substantially parallel to each other) and an area changing capacitor between first conductor plate 312 and the second conductor plate 316 (e.g., substantially parallel to each other) while a uniform voltage is applied between the first electrode 318 (e.g., which connects to the lower conductor plate 308 and the first conductor plate 312) and the second electrode 320 (e.g., which connects to the upper conductor plate 306 and the second conductor plate 316).

Alternatively, two separate sets of electrodes may be connect to each of the upper conductor plate 306/lower conductor plate 308 and the first conductor plate 312/second conductor plate 316. As will be illustrated in details in FIG. 3C, a force or a pressure 322 applied on top of the upper housing 302 causes the upper conductor plate 306 to move close to the lower conductor plate 308 and/or the first conductor plate 312 to move closer to the second conductor plate 316, thus resulting in a change in capacitance (e.g., due to a change in the distance between the upper conductor palate 306 and the lower conductor plate 308 and/or a change in the area overlapped by the first conductor plate 312 and the second conductor plate 316).

The combination of the gap changing capacitor and the area changing capacitor in accordance with embodiments of the present invention may provide a wider range of capacitance measured by the microelectromechanical capacitive device than solely relying on either the gap changing capacitor or the area changing capacitor. The working or features of the microelectromechanical capacitive device is similar to the workings of the gap changing capacitive device of FIGS. 1A, 1B, and 1C and/or the area changing capacitive device of FIGS. 2A, 2B, and 2C in principle.

In one example embodiment, the microelectromechanical capacitive device may contain two capacitors with each capacitor with a pair of conductor plates (e.g., parallel to each other). A circuit (e.g., internal or external to the microelectromechanical capacitive device) connects to electrodes of the microelectromechanical capacitive device to measure changes taking place in the two capacitors due to a force or a pressure applied to the housing. One of the two capacitors may be based on the gap changing capacitor of FIGS. 1A, 1B, and 1C, whereas the other one of the two capacitors may be based on the area changing capacitor of FIGS. 2A, 2B, and 2C.

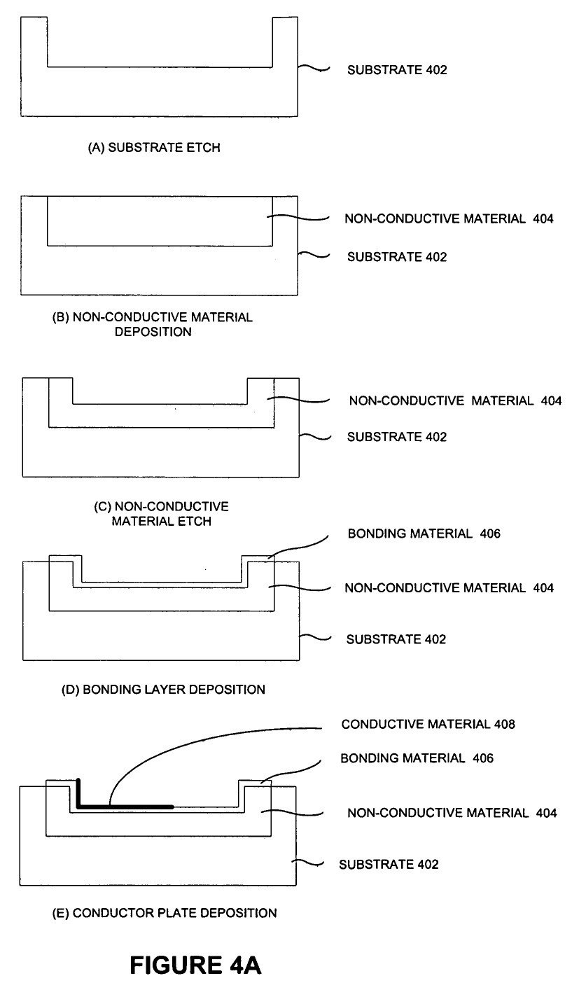

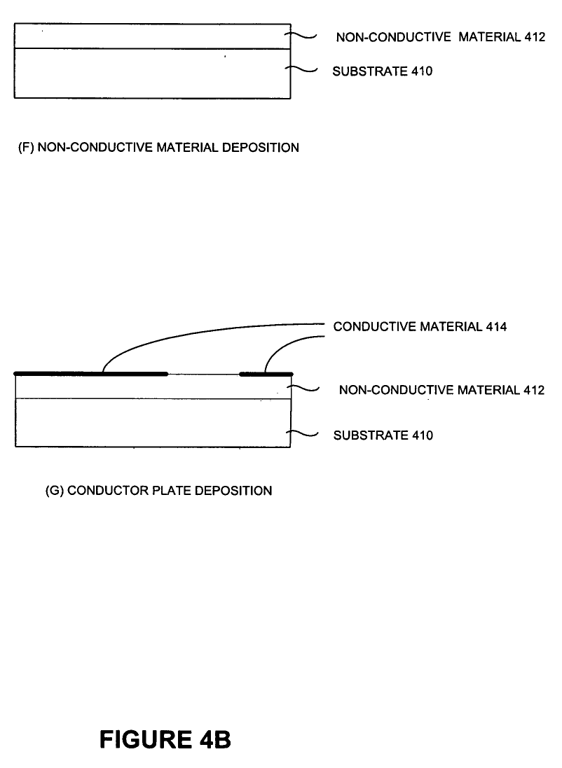

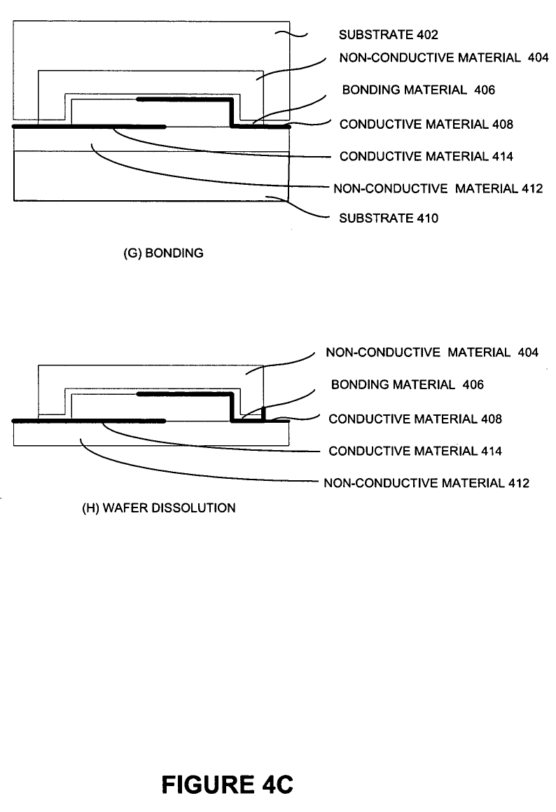

FIG. 4A is an exemplary process for fabricating an upper part of the housing of the gap changing microelectromechanical capacitive device in FIGS. 1A, 1B, and 1C, in accordance with embodiments of the present invention. As illustrated in step (A) of FIG. 4A, a cavity is formed by etching (e.g., a wet chemical etching, a dry etching, etc.) a substrate 402 (e.g., a silicon, a glass, etc.) once a mask is applied to the substrate 402. In step (B), a non-conductive material 404 or a semiconductor material (e.g., a ceramics, a paper, a mica, a polyethylene, a glass, and a metal oxide) is deposited on the substrate 402 using a physical vapor deposition, a chemical vapor deposition, and/or a planarization.

In one example embodiment, the non-conductive material 404 or the semiconductor material may be a material resilient to a force or pressure applied to the non-conductive material 404 (e.g., the upper housing of the microelectromechanical capacitive device), such as a silicon-on-insulator (SOI) wafer, a single crystal silicon wafer, and a polysilicon wafer. The resilient material may extend the lifecycle of the microelectromechanical capacitive device as it is able to withstand wear and tear caused by forces or pressures applied to the non-conductive material 404. The resilient material (e.g., the non-conductive material 404) may be formed in a desired membrane thickness (e.g., several microns to several tens microns in one embodiment).

In step (C), the non-conductive material 404 is etched using the physical vapor deposition, the chemical vapor deposition, and/or the planarization to form an inner cavity of the microelectromechanical capacitive device. This etching step may be also used to form the desired membrane thickness for the non-conductive material 404. In step (D), a bonding material 406 (e.g., a polysilicon, an amorphous silicon, etc. of about 100 to 10,000 angstroms in one embodiment) is deposited over the inner surface of the non-conductive material 404 using a low pressure chemical vapor deposition (LPCVD), a plasma enhanced chemical vapor deposition (PECVD), an atmospheric pressure chemical vapor deposition (APCVD), or by sputtering.

In step (E), a conductive material 408 (e.g., a metal such as copper or gold or a non-metal such as a graphite or a plasma) may be deposited on to a designated area on the surface of the bonding material 408 and/or the non-conductive material 404. The conductive material 408 may form the upper conductor plate 106 of FIG. 1 in the middle and the second electrode 112 toward the edge of the upper housing 102 made of the non-conductive material 404.

In other example embodiments, steps (C), (D), and (E) of FIG. 4A may be altered to form the area changing microelectromechanical capacitive device of FIGS. 2A, 2B, and 2C as well as the microelectromechanical capacitive device having both the gap changing and area changing capacitors of FIGS. 3A and 3B. For instance, in between steps (C) and (D), deposition and/or etching steps may be taken to form the support structure 206 of FIG. 2 for the first conductor plate 208.

FIG. 4B is an exemplary process for fabricating a lower part of the housing of the gap changing microelectromechanical capacitive device in FIGS. 1A, 1B, and 1C, in accordance with embodiments of the present invention. In step (F), a non-conductive material 412 or a semiconductor material (e.g., a ceramic, a paper, a mica, a polyethylene, a glass, a metal oxide, etc.) is deposited on a substrate 410 (e.g., a silicon or a glass). The layer of the non-conductive material 412 forming the lower part of the housing may be thicker than the layer of the non-conductive material 404 forming the upper part of the housing.

In step (E), a conductive material 414 (e.g., a metal such as copper or gold or a non-metal such as a graphite, a plasma, etc.) may be deposited onto a designated area on the surface of the non-conductive material 412. The conductive material 414 may form the lower conductor plate 108 of FIG. 1 in the middle and the first electrode 110 and the second electrode 112 towards the edges of the lower housing 104 made of the non-conductive material 412. The process for fabricating the lower part of the area changing microelectromechanical capacitive device of FIGS. 2A, 2B, and 2C and/or the microelectromechanical capacitive device having both the gap changing and area changing capacitors of FIGS. 3A and 3B may be similar to the process described above.

FIG. 4C is an exemplary process for assembling the upper housing formed in FIG. 4A and the lower housing formed in FIG. 4B, in accordance with embodiments of the present invention. In step (G) of FIG. 4C, the upper housing formed through the steps illustrated in FIG. 4A is bonded with the lower housing formed through the steps illustrated in FIG. 4B. In step (H), the substrate 402 and the substrate 410 are dissolved by a chemical etching process (e.g., with ethylene diamine pyrocatechol water, KOH, etc.)

The process for assembling the upper housing and the lower housing for the area changing microelectromechanical capacitive device of FIGS. 2A, 2B, and 2C and/or the microelectromechanical capacitive device having both the gap changing and area changing capacitors of FIGS. 3A and 3B may be similar to the process described above.

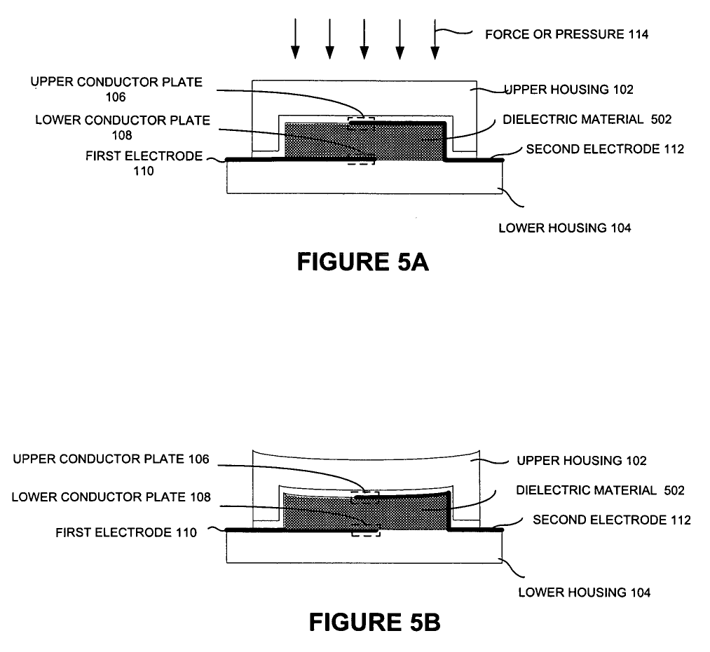

FIGS. 5A and 5B are exemplary cross sectional views of the gap changing microelectromechanical capacitive device of FIGS. 1A, 1B, and 1C with a solid dielectric material filling the inner cavity of the housing, in accordance with embodiments of the present invention. In FIG. 5A, the force or pressure 114 is applied to the upper housing 102 causing the upper housing to distort, thus displacing the upper conductor plate 106. The dielectric material 502 may be a solid (e.g., a porcelain, mica, glass, plastic, metal oxide, etc.), a semisolid (e.g., having properties of solids and liquids), a liquid (e.g., a distilled water), and/or a gas (e.g., a dry air). The dielectric material 502 may be a vacuum as well.

In the case of the liquid or the gas dielectric, the upper housing 102 of the gap changing microelectromechanical capacitive device may be distorted when the force or pressure 114 applied to the upper housing is significantly bigger than the force or pressure present in the inner cavity of the gap changing microelectromechanical capacitive device. This may in turn cause the upper housing 102 to collapse. To prevent collapse, a spacer may be inserted between the upper housing 102 and the lower housing 104.

Alternatively, a solid dielectric material (e.g., the porcelain, mica, glass, plastic, metal oxide, etc.) may be used to fill the inner cavity. The solid dielectric may preserve the shape of the upper housing 102 at the expense of measurement sensitivity. In yet another embodiment, more resilient material (e.g., a silicon-on-insulator (SOI) wafer, a single crystal silicon wafer, a polysilicon wafer, etc.) may be used to form the housing of the gap changing microelectromechanical capacitive device.

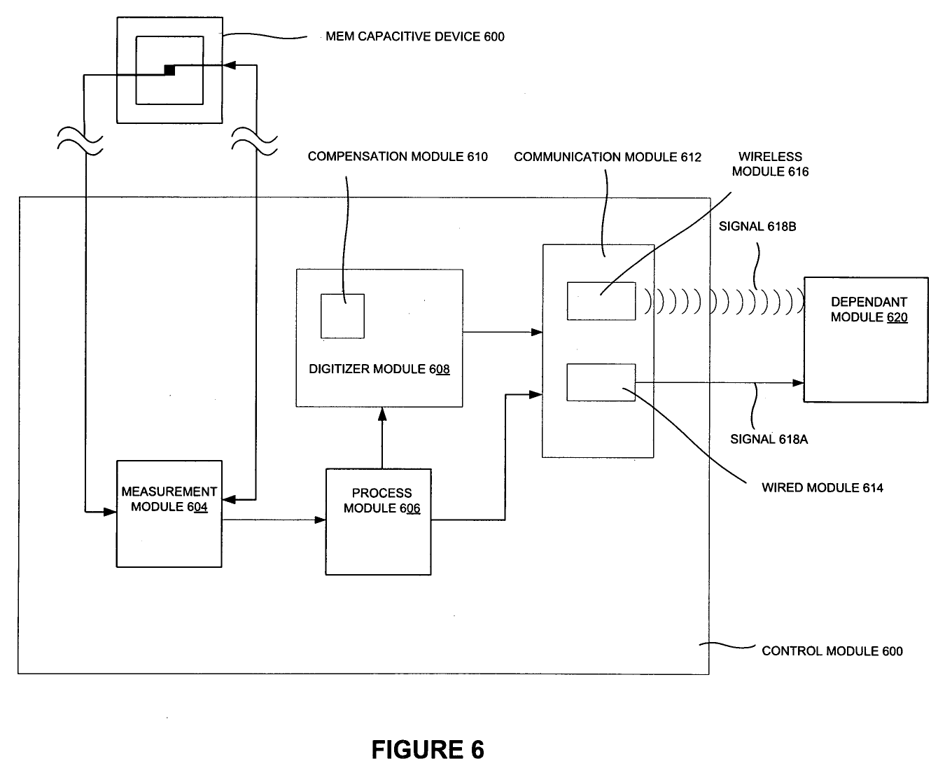

FIG. 6 is an exemplary block diagram of a microelectromechanical capacitive device 600 communicating with a dependant device 620, in accordance with embodiments of the present invention. In FIG. 6, a force or pressure 602 deflects the upper housing of the microelectromechanical capacitive device 600. An electronic circuit (e.g., a measurement module 604) may be used to measure the capacitance generated by the displacement between two conductor plates (e.g., such as the upper conductor plate 106 and the lower contact plate 108) in the case of the gap changing microelectromechanical capacitive device of FIGS. 1A, 1B, and 1C and/or by the change in the area overlapped by two conductor plates (e.g., such as the first conductor plate 208 and the second conductor plate 212) in the case of the area changing microelectromechanical capacitive device of FIGS. 2A, 2B, and 2C when the force or pressure 602 is applied to the MEM capacitive device 600.

Next, the capacitance (e.g., due to the distance change and/or area change) may be converted to a voltage and/or frequency signal. The capacitance, voltage, and/or frequency may be processed by a process module 606 (e.g., a microprocessor). The process module 606 may execute a set of instructions associated with the digitizer module 608 (e.g., an analog to digital converter), the compensation module 610, and/or the communication module 612. The digitizer module 608 may convert the capacitance, voltage, and/or frequency to a digital value.

The compensation module 610 may subtract one or more distortion factors from the capacitance measured by the MEM capacitive device 600 to minimize the effect of the one or more distortion factors ascribed to the MEM capacitive device 600. The communication module 612 includes a wired module 614 and a wireless module 616. The wired module 614 may communicate a universal serial bus (USB) signal, a voltage signal, a frequency signal, and/or a current signal in an analog and/or digital format to the dependant device 620. The wireless module 616 may wirelessly communicate with the dependent device based on one or more of a wireless universal serial bus (USB), a Wi-Fi (e.g., of a wireless local area network), a Bluetooth (e.g., of a wireless personal area network), and/or a Zigbee (e.g., of the wireless personal are network).

Additionally, a reference sensor may generate a capacitance based on one or more environmental factors (e.g., a humidity, a temperature, an air pressure, a radiation, etc.). Therefore, the environmental factors may be removed from the measurement of capacitance generated by the MEM capacitive device 600 when the force or pressure 602 is applied.

In one example embodiment, a system includes a microelectromechanical capacitive device (e.g., which is based on a capacitor encompassed in a housing to measure a capacitance change in the capacitor based on a deflection of the housing due to a force or a pressure applied to the housing) and a device dependent to the microelectromechanical capacitive device. The microelectromechanical capacitive device is internal or external to the device. Additionally, the microelectromechanical capacitive device is connected to the device based on a wired or wireless technology.

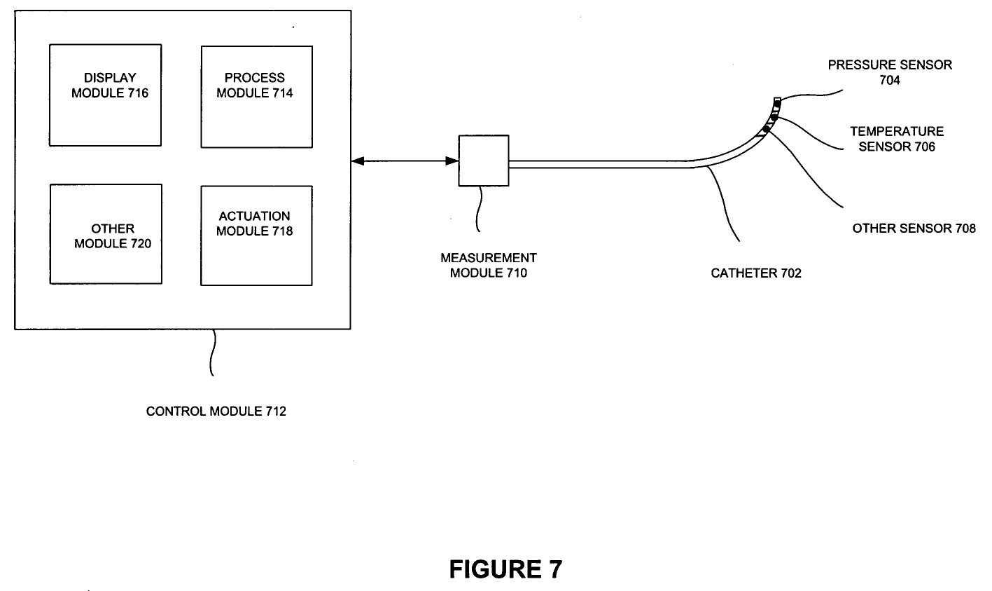

FIG. 7 is an exemplary diagram of a catheter system based on one or more sensors, according to embodiments of the present invention. As illustrated in FIG. 7, the catheter system may include a catheter 702, a measurement module 710, and a control module 712. The catheter 702 may be a tube that can be inserted into a body cavity, duct or vessel, thus allowing drainage or injection of fluids or access by surgical instruments. The catheter 702 is equipped with a pressure sensor 704, a temperature sensor 706, and other sensor 708 (e.g., a vibration sensor, a humidity sensor, an aural sensor, a motion sensor, etc.).

The sensors may be connected to the measurement module 710 through one or more conductor wires. The measurement module 710 may include a circuit to measure changes detected by the sensors, a microprocessor to carry out one or more applications associated with the catheter 702, and other modules to increase accuracy of measurements taken by the sensors and/or communicate with the control module 712. In one example embodiment, the measurement module 710 may communicate with the control module 712 by a wired channel and/or a wireless channel.

The control module 712 includes a process module 714, a display module 716, an actuation module 718, and other module 720. The process module 714 may be used to receive, transform, manipulate, and/or analyze the measurements taken by the sensors. The display module 716 may display views taken or processed by a camera (e.g., a miniature) inserted into the catheter 702. In one example embodiment, the display module 716 may display the measurements taken by the sensors and/or one or more analyses based on the measurements. The actuation module 718 is used to control the movements of the catheter 702 (e.g., using a motor).

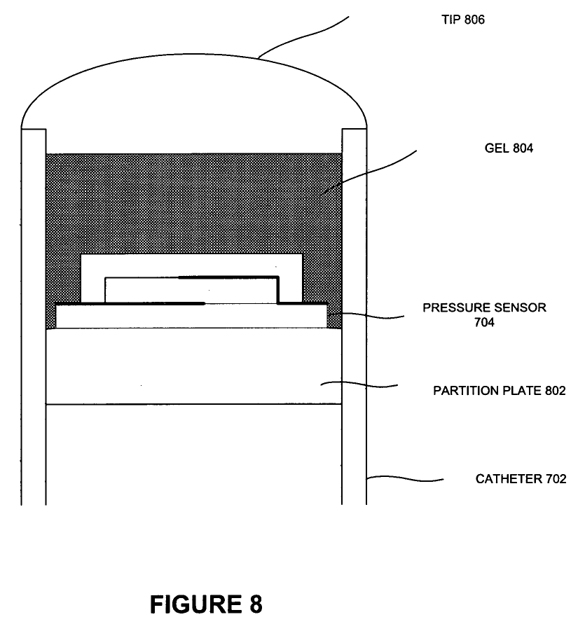

FIG. 8 is an exemplary vertical cross sectional view of the tip end of the catheter 702 of FIG. 7 equipped with a MEM capacitive device, according to embodiments of the present invention. As illustrated in FIG. 8, the pressure sensor 704 (e.g., the gap changing MEM capacitive device of FIG. 1A, the area changing MEM capacitive device of FIG. 2A, and their combination as in FIG. 3A) is mounted on a partition plate 802 which is firmly attached to the wall of the catheter 702. A gel 804 (e.g., a silica gel) is applied on top of the pressure sensor 704 to soften the effect of a force or pressure applied on a tip 806.

In one example embodiment, the catheter 702 may be inserted to perform a Chorionic Villi Sampling (CVS) which is performed between 10 and 12 weeks of pregnancy to detect genetic abnormalities as amniocentesis. The CVS involves inserting a catheter or needle into the womb and extracting some of the chorionic villi (e.g., which are cells from the tissue that will become the placenta). The test, if mishandled, could cause a miscarriage. The pressure sensor 704 may be used to minimize that risk (e.g., and/or pain or discomfort to the patient) by measuring even small force or pressure applied to the tip 806 when the catheter 702 comes in contact with a sensitive area of the womb.

Additionally, the pressure sensor 704 based on MEMS technology can sensitively respond to a tiny force or pressure often undetected by other types of sensor (e.g., a strain-gauge sensor). Furthermore, the pressure sensor 704 may be more economical because it consumes less energy and/or more durable.

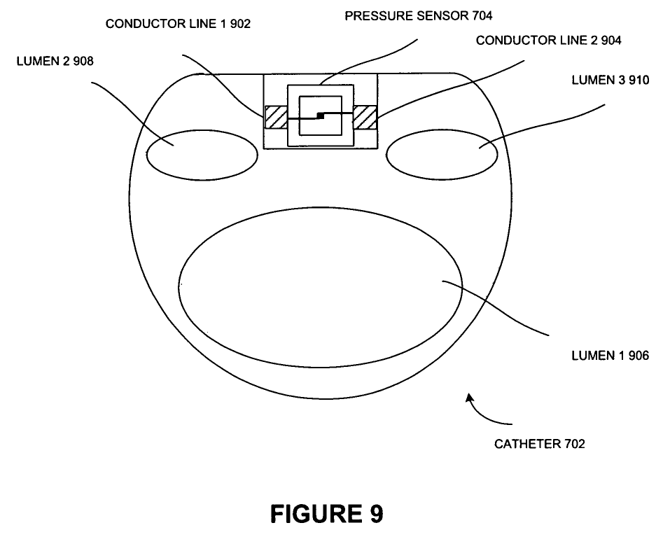

FIG. 9 is a horizontal cross sectional view of the tip end of the catheter of FIG. 7, according to embodiments of the present invention. In FIG. 9, the catheter 702 has three lumens (e.g., cavities) formed to accommodate miniature equipments inserted through them. For instance, surgical equipments may be inserted through the lumens (e.g., a lumen 1 906, a lumen 2 908, and/or a lumen 3 910) to operate a patient. A medicine may be delivered through the lumens as well. Additionally, one or more conductor lines (e.g., a conductor line 1 902, a conductor line 2 904, etc.) may be used to connect the pressure sensor 704 (e.g., and/or to other sensors) to the measurement module 710.

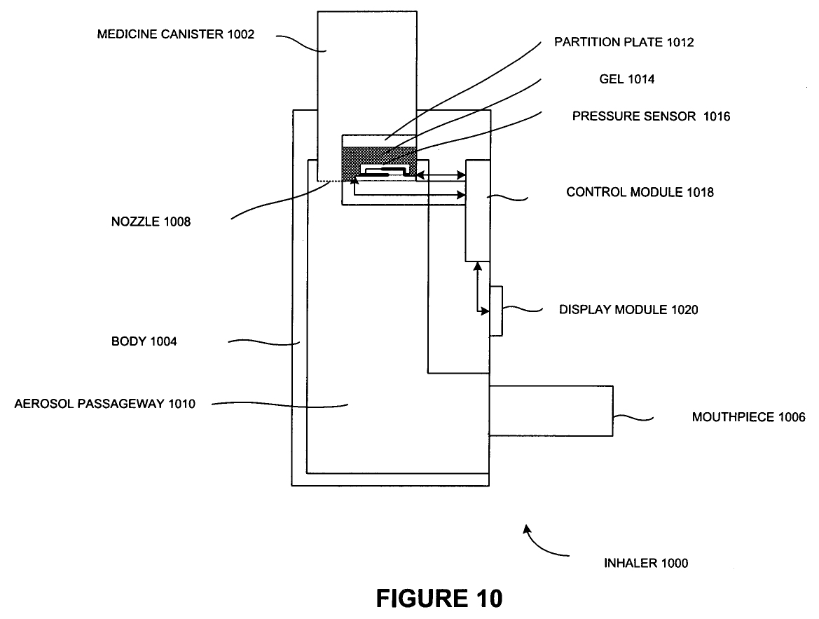

FIG. 10 is an exemplary diagram of an inhaler 1000 having a pressure sensor 1016 to weigh medicine remaining in a medicine canister 1002 of the inhaler 1000, according to embodiments of the present invention. As illustrated in FIG. 10, the inhaler 1000 is made up of a medicine canister 1002 (e.g., replaceable), a body 1004, and a mouthpiece 1006. Medicine inside the medicine canister 1002 may be transferred to the mouthpiece 1006 mechanically through a nozzle 1008 when a user presses a lever or button to force the flow of medicine from the medicine canister 1002.

In one example embodiment, the medicine may be released from the medicine canister 1002 through the nozzle 1008 automatically when the user put his or her mouth to the mouthpiece 1006 and breathe the air in. The medicine released by the medicine canister 1002 may be in an aerosol form, and may get to the mouthpiece 1006 through an aerosol passage way 1010.

In another example embodiment, a pressure sensor 1016 may be used to gauge the weight of the medicine canister 1002 or the medicine remaining inside the medicine canister 1002 by measuring the weight of the medicine canister 1002. In one example embodiment, the weight of the medicine canister 1002 may be directly applied to the pressure sensor 1016. In another example embodiment, the weight of the medicine canister 1002 may be buffered by a partition plate 1012 and a gel 1014 (e.g., a silica gel) to prevent the force of the medicine canister 1002 from directly impacting the pressure sensor 1016.

The pressure sensor 1016 is connected to a control module 1018 (e.g., a CMOS based circuit) which measures, processes, and/or communicate measurements taken by the pressure sensor 1016. The display module 1020 may exhibit the status of the medicine canister 1002. For example, a number of light emitting diodes (LEDs) may be used as a status indicator of the medicine canister. A green LED light may indicate that there is enough medicine. A yellow LED light may indicate that the medicine is running out, and a red light may indicate that the medicine has run out. This feature of the inhaler 1000 may be crucial for patients with certain diseases, such as an acute case of asthma.

A power source (e.g., a battery) may connect to electrical and/or mechanical component and/or module present in the inhaler 1000. In one example embodiment, one or more of the pressure sensor 1016 may be used to weigh the medicine canister 1002. Furthermore, one or more of the pressure sensor 1016 may be used to release a set amount of medicine from the medicine canister 1002 through configuring the control module 1018 (e.g., which may be configured to stay open the nozzle 1008 for a set period of time).

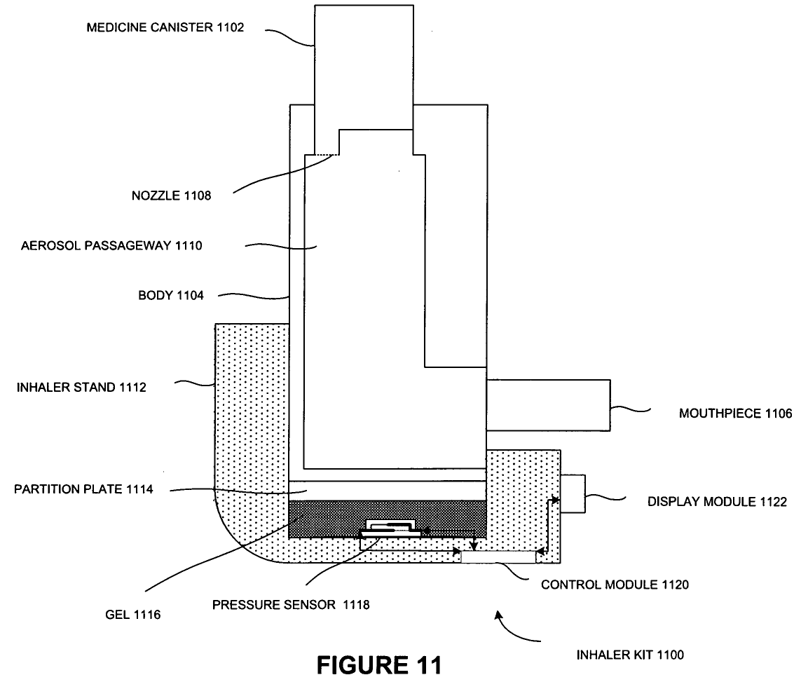

FIG. 11 is an exemplary diagram of an inhaler kit 1100 with an inhaler and an inhaler stand 1112 equipped with a pressure sensor 1118 to weigh medicine remaining in a medicine canister 1102 of the inhaler, according to embodiments of the present invention. As illustrated in FIG. 11, the inhaler kit 1100 is made up of the medicine canister 1102 (e.g., replaceable), a body 1104, and a mouthpiece 1106.

Unlike the inhaler 1000 of FIG. 10, the pressure sensor 1118 installed to the inhaler stand 1112 rather than to the inhaler to weigh the medicine canister 1102 or the medicine present inside the medicine canister 1102 using the pressure sensor 1118. The working of the pressure sensor 1110 in response to a force or pressure applied on it is similar to the case of the pressure sensor 1016 in FIG. 10. The difference may be that the weight of the medicine canister 1102 is measured when the inhaler is placed on the inhaler stand 1112. A control module 1120, a display module 1122 and a power source (e.g., which is not shown here) may work similar to their counterparts in FIG. 10.

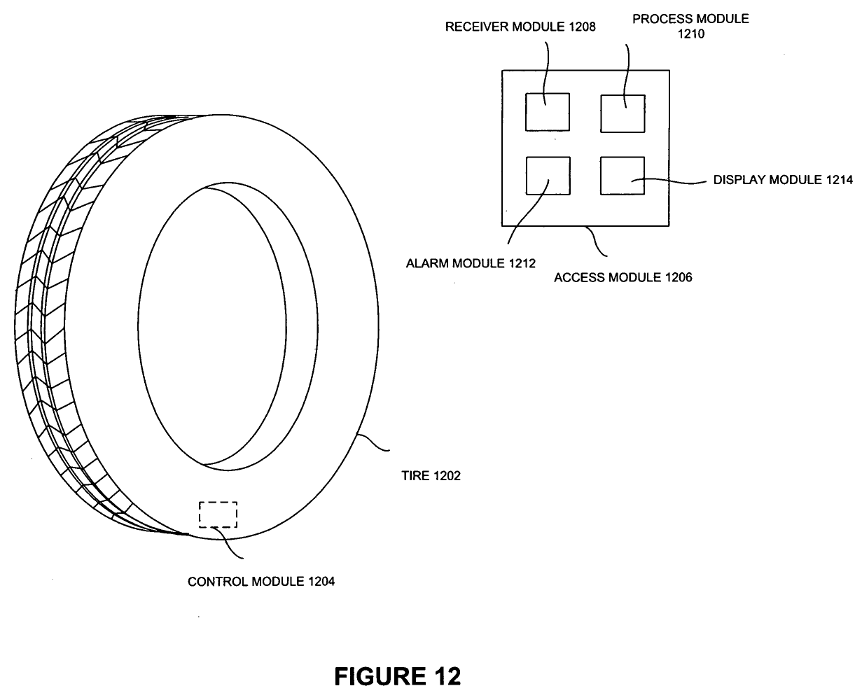

FIG. 12 is an exemplary diagram of a control module 1204 of a tire 1202 interacting with an access module 1206 to check the tire pressure, according to one embodiment. As illustrated in FIG. 12, a control module equipped with a pressure sensor may be used to continually check the pressure of the tire 1202 (e.g., of an automobile) and/or communicate with the access module 1206 (e.g., which may be located near the driver's seat of the automobile).

The control module 1204 may be installed inside the tire 1202, and may consume the minimum amount of power (e.g., to stay active for the life of the tire 1202). A MEM capacitive sensor (e.g., the gap changing MEM capacitive device of FIGS. 1A, 1B and 1C, the area changing MEM capacitive device of FIGS. 2A, 2B, and 2C, and their combinations illustrated in FIGS. 3A and 3B) may enable its battery to last longer because the MEM capacitive sensor may require less energy than its counterpart (e.g., a resistor based sensor or other types of sensor in larger scale).

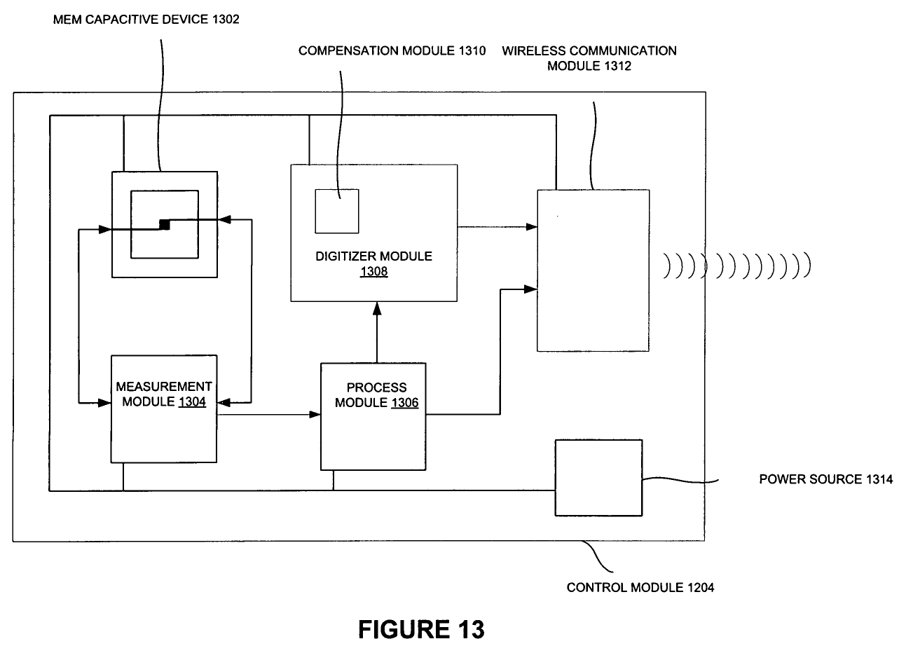

In one example embodiment, the control module 1204 (e.g., which may include the pressure sensor and a number of modules as illustrated in FIG. 13) may be configured to transmit only when the pressure of the tire 1202 falls below a threshold level. Additionally, the frequency of measurement taken by the pressure sensor may be configured in such a way to save energy even further. For instance, the measurement may be taken every 10 seconds rather than continuously.

The access module 1206 includes a receiver module 1208, a process module 1210, an alarm module 1212, and a display module 1214. The receiver module 1206 may include an antenna and a receiver circuit. The process module 1210 (e.g., a microprocessor) may be used to execute a set of instructions to access the measurements taken by the pressure sensor. The alarm module 1212 may generate an alarm (e.g., aural or visual alarm) when the pressure of the tire 1202 falls below the threshold value. The display module 1214 may display the status of the tire 1202 (e.g., on a panel of the automobile).

FIG. 13 is an exemplary block diagram of the control module 1204 of FIG. 12, according to embodiments of the present invention. In FIG. 13, a force or pressure deflects the upper housing of the microelectromechanical (MEM) capacitive device 1302. An electronic circuit (e.g., a measurement module 1304) may be used to measure the capacitance generated by the inner air pressure of the tire 1202. Next, the capacitance may be converted to a voltage and/or frequency. The capacitance, voltage, and/or frequency may be processed by a process module 1306 (e.g., a microprocessor). The process module 1306 may execute a set of instructions associated with a digitizer module 1308 (e.g., an analog to digital converter), a compensation module 1310, and/or a communication module 1312. The digitizer module 1308 may convert the capacitance, voltage, and/or frequency to a digital value.

The compensation module 1310 may subtract one or more distortion factors from the capacitance measured by the MEM capacitive device 1302 to minimize the effect of the one or more distortion factors ascribed to the MEM capacitive device 1302. The wireless communication module 1312 may wirelessly communicate with the control module 1204 based on one or more of wireless universal serial bus (USB), a Wi-Fi (e.g., of a wireless local area network), a Bluetooth (e.g., of a wireless personal area network), and/or a Zigbee (e.g., of the wireless personal are network). Additionally, a power source 1314 may supply power to operate all the electrical and/or mechanical components of the control module 1204.

In addition, the power source 1314 may include an energy harvesting module that acquires a kinetic energy of the tire when the tire is moving, stores the kinetic energy, and powers the measurement module when it obtains the tire pressure measurement. Various methods may be used to acquire a kinetic energy of the tire, including piezoelectric crystals or fibers that generate a voltage whenever they are mechanically deformed. Other methods for acquiring power include the pyroelectric effect, which converts a temperature change into electrical current or voltage, and thermoelectric effects, in which a thermal gradient formed between two dissimilar conductors produces a voltage. Energy may be stored in a battery, a capacitor, or as potential energy in a mechanical device, such as a spring.

The previous description of the disclosed embodiments is provided to enable any person skilled in the art to make or use the present invention. Various modifications to these embodiments will be readily apparent to those skilled in the art, and the generic principles defined herein may be applied to other embodiments without departing from the spirit or scope of the invention. Thus, the present invention is not intended to be limited to the embodiments shown herein but is to be accorded the widest scope consistent with the principles and novel features disclosed herein.

What is claimed is:

1. A system of a microelectromechanical capacitive device, comprising:
a housing formed when a nonconductive material is deposited on a substrate;
a conductive plate mechanically coupled to the housing;
an additional housing coupled to the housing; and
an additional conductive plate that is substantially parallel to the conductive plate, wherein the additional conductive plate is coupled to the additional conductive plate.

2. The system of claim 1, wherein the additional housing is formed when an additional nonconductive material is deposited on an additional substrate.

3. The system of claim 1, wherein the substrate and the additional substrate are dissolved using a chemical etching process when the housing and the additional housing are coupled.

4. The system of claim 1, wherein the microelectromechanical capacitive device is used to detect a change in capacitance when a gap between the conductive plate and the additional conductive plate is changed.

5. The system of claim 1, wherein the microelectromechanical capacitive device is used to detect a change in capacitance when an overlapping area of the conductive plate and of the additional conductive plate is changed.

6. The microelectromechanical capacitive device of claim 4, further comprising a supplementary pair of conductive plates, wherein the microelectromechanical capacitive device is used to detect a change in capacitance when an overlapping area of the supplementary pair of conductive plates is changed.

7. The system of claim 1, further comprising a reference sensor coupled to the housing to generate a capacitance based on an environmental factor and to compensate a measurement affected by the environmental factor.

8. The system of claim 1, further comprising a plurality of capacitors in the housing, wherein a difference in capacitance between the plurality of capacitors is used to detect an uneven force when it is applied to the housing.

9. The system of claim 1, further comprising at least one of a semisolid and a solid dielectric material located between the conductive plate and the additional conductive plate.

10. The system of claim 1, further comprising a tip of a catheter that is mechanically coupled to the housing, wherein the system detects a force when it is applied to the tip of the catheter and it causes an additional force to act on the housing.

11. The system of claim 1, further comprising a container coupled to the housing.

12. The system of claim 11, wherein the container holds a medicine, and wherein a weight of the medicine is determined by a capacitance between the conductive plate and the additional conductive plate when a force is applied to the housing.

13. The system of claim 1, further comprising:
a tire physically coupled to the housing;
a measurement module to obtain a tire pressure measurement when a force is applied to the housing, wherein the measurement module is electrically coupled to the conductive plate and the additional conductive plate;
a communication module, wherein the communication module is used to communicate the tire pressure measurement when a force is applied to the housing; and
an energy harvesting module, wherein the energy harvesting module acquires a kinetic energy of the tire when the tire is moving, stores the kinetic energy, and powers the measurement module when it obtains the tire pressure measurement.

14. The system of claim 13, wherein the tire pressure measurement is communicated using at least one of wireless universal serial bus, Wi-Fi, Bluetooth, and Zigbee.

15. A method of a microelectromechanical capacitive device, comprising:
depositing a nonconductive material on a substrate to form a housing;
depositing an additional nonconductive material on an additional substrate to form an additional housing;
mechanically coupling a conductive plate to the housing;
mechanically coupling an additional conductive plate to the additional housing; and
forming the microelectromechanical device, wherein the microelectromechanical device is formed when the housing and the additional housing are mechanically coupled such that the conductive plate and the additional conductive plate are substantially parallel.

16. The method of claim 15, further comprising dissolving the substrate and the additional substrate using a chemical etching process.

17. The method of claim 15, wherein the microelectromechanical capacitive device is used to detect a change in capacitance when a gap between the conductive plate and the additional conductive plate is changed.

18. The method of claim 15, wherein the microelectromechanical capacitive device is used to detect a change in capacitance when an overlapping area of the conductive plate and of the additional conductive plate is changed.

19. A method of a microelectromechanical capacitive device, comprising:
receiving an applied force with a housing formed when a nonconductive material is deposited on a substrate;
deflecting the housing in response to the applied force;
shifting the conductive plate coupled to the housing relative to an additional conductive plate using the deflection of the housing, wherein the additional conductive plate is mechanically coupled to an additional housing; and
detecting a change in capacitance using a change of at least one of a gap between the conductive plate and the additional conductive plate and an overlapping area of the conductive plate and the additional conductive plate.

20. The method of claim 19, further comprising:
detecting a capacitance based on an environmental factor using a reference sensor in the housing; and
compensating a measurement affected by the environmental factor.
